(19) United States
(12) Patent Application Publication
(10) Pub. No.: US 2009/0097337 A1
(43) Pub. Date: Apr. 16, 2009

(54) SEMICONDUCTOR STROAGE DEVICE

(75) Inventor: Katsuyuki FUJITA, Yokohama-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/248,561

(22) Filed: Oct. 9, 2008

(30) Foreign Application Priority Data
Oct. 15, 2007 (JP) 2007-267695

(51) Int. Cl. G11C 7/12; G11C 7/06

(52) U.S. Cl. 365/189.15

(57) ABSTRACT

This disclosure concerns a memory including: memory cells having sources, drains, gates and floating bodies; word lines connected to gates of the memory cells and arranged in a first direction; first bit lines and second bit lines connected to sources or drains of the memory cells and arranged alternately in a second direction intersecting with the first direction; and first and second sense amplifiers provided in correspondence with the first and the second bit lines, wherein in a data reading operation, the first sense amplifier activates the first bit lines to sense data via the first bit lines in a state where voltage of the second bit lines is fixed, and after sensing of the data of the first bit line, the second sense amplifier activates the second bit lines to sense data via the second bit lines in a state where voltage of the first bit lines is fixed.

### CROSS-REFERENCE TO RELATED APPLICATIONS

This application is based upon and claims the benefit of priority from the prior Japanese Patent Application No. 2007-267695, filed on Oct. 15, 2007, the entire contents of which are incorporated herein by reference.

### BACKGROUND OF THE INVENTION

1. Field of the Invention

The present invention relates to a semiconductor storage device such as an FBC (Floating Body Cell) memory device for storing data by the number of carriers in a floating body.

2. Related Art

In recent years, as a semiconductor storage device expected as a memory replacing a 1T (transistor)-1C (Capacitor) DRAM, there is an FBC memory device. In the FBC memory device, an FET (Field Effect Transistor) having a floating body (hereinbelow, also called body) on an SOI (Silicon On Insulator) substrate, and data “1” or “0” is stored according to the number of majority carriers stored in the body.

For example, a state where the number of holes stored in the body in an FBC made as an N-type FET is set as the data “1”, and a state where the number of holes is small is set as the data “0”. A memory cell storing the data “0” is called a “0” cell, and a memory cell storing the data “1” is called a “1” cell.

In the FBC memory having an open bit line configuration, two bit lines connected to a memory cell arrays on both of which sense amplifiers are provided are connected. The sense amplifier receives reference data via one of its two bit lines and detects information data transmitted onto the other bit line on the basis of the reference data.

However, when it is assumed that a memory cell to be read is the “1” cell and both of two memory cells sharing a word line with the memory cell to be read and adjacent to the memory cell are the “0” cells, there is the possibility that the sense amplifier erroneously detects data in the memory cell to be read. The reason is that noise is included in read information data due to capacitive coupling between a bit line connected to the memory cell to be read and two bit lines adjacent to the bit line.

On the contrary, also in the case where a memory cell to be read is the “0” cell and both of two memory cells sharing a word line with the memory cell to be read and adjacent to the memory cell are the “1” cells, there is the possibility that the sense amplifier erroneously detects data.

### SUMMARY OF THE INVENTION

A semiconductor storage device according to an embodiment of the present invention comprises a plurality of memory cells having sources, drains, and gates, including floating bodies in electric floating states, the memory cells storing data according to the number of carriers in the floating bodies; a plurality of word lines connected to gates of the memory cells and arranged in a first direction; a plurality of first bit lines and a plurality of second bit lines connected to sources or drains of the memory cells and arranged alternately in a second direction intersecting with the first direction; and first and second sense amplifiers provided in correspondence with the first and the second bit lines and sensing data of the memory cells,

wherein in a data reading operation, the first sense amplifier activates the first bit lines to sense data via the first bit lines in a state where voltage of the second bit lines is fixed, and

after sensing of the data of the first bit line, the second sense amplifier activates the second bit lines to sense data via the second bit lines in a state where voltage of the first bit lines is fixed.

### BRIEF DESCRIPTION OF THE DRAWINGS

FIG. 1 is a block diagram showing the configuration of an FBC memory as a first embodiment of the invention;

FIG. 2 is a diagram showing the arrangement relation between the memory cell array MCA and the sense amplifier S/A in the first embodiment;

FIG. 3 is a cross section showing the structure of the memory cell MC;

FIG. 4 is a circuit diagram showing the connection relation of the memory cell MC, the bit line BL, the word line WL, and the source line SL;

FIG. 5 is a circuit diagram showing an example of the configuration of the sense amplifier S/A;

FIGS. 6A and 6B are timing charts showing data reading operation of an FBC memory device according to the embodiment;

FIG. 7 is a schematic diagram showing an end sense amplifier line SAE;

FIG. 8 shows the configuration of an FBC memory as a second embodiment of the present invention; and

FIG. 9 is a circuit diagram showing the configuration of the sense amplifiers S/A1 and S/A2 in the second embodiment.

### DETAILED DESCRIPTION OF THE INVENTION

Embodiments of the present invention will be described below with reference to the drawings. The present invention is not limited to the embodiments.

### First Embodiment

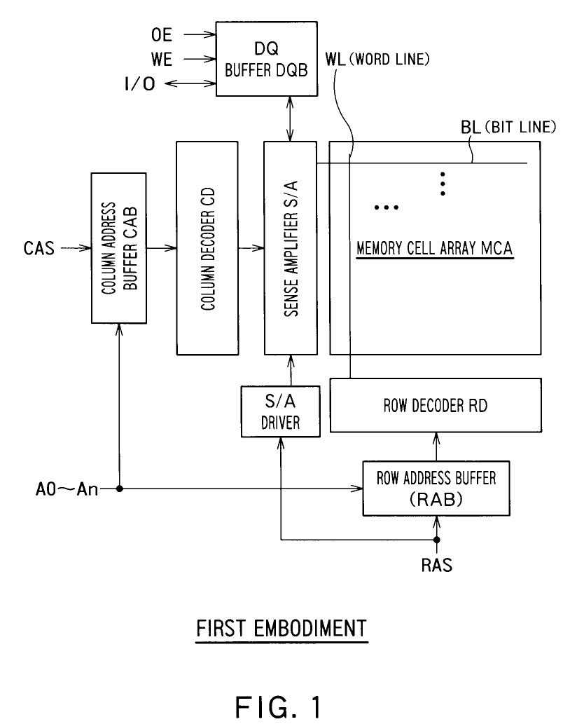

FIG. 1 is a block diagram showing the configuration of an FBC memory as a first embodiment of the invention. The FBC memory has a memory cell array MCA and a sense amplifier S/A. The memory cell array MCA is made of a number of memory cells two-dimensionally disposed in a matrix. A word line WL and a source line SL are connected to memory cells arranged in a row direction as a second direction. The bit lines BL are connected to the memory cells arranged in a column direction as a first direction perpendicular to the row direction.

The sense amplifier S/A is connected to the bit line BL. The sense amplifier S/A reads data of a memory cell via the bit line BL or writes data to a memory cell via the bit line BL. The sense amplifier S/A is provided in correspondence with the bit line BL or a bit line pair.

A row address buffer RAB receives a row address signal RAS from the outside, temporarily stores it, and outputs it to a row decoder RD. The row decoder RD selects a word line WL in accordance with the row address signal RAS. A column address buffer CAB receives a column address signal CAS from the outside, temporarily stores it, and outputs it to the column decoder CD. The column decoder CD selects a bit line of the memory cell array MCA in accordance with a column address signal CAS.

A DQ buffer DQB is connected between the sense amplifier S/A and an input/output unit I/O. The DQ buffer DQB temporarily stores read data from the sense amplifier S/A to output the read data to the outside or temporarily stores write data from the outside to send the write data to the sense amplifier S/A. The data output to the outside in the DQ buffer DQB is controlled by an output enable signal OE. The data writing from the outside in the DQ buffer DQB is controlled by a write enable signal WE.

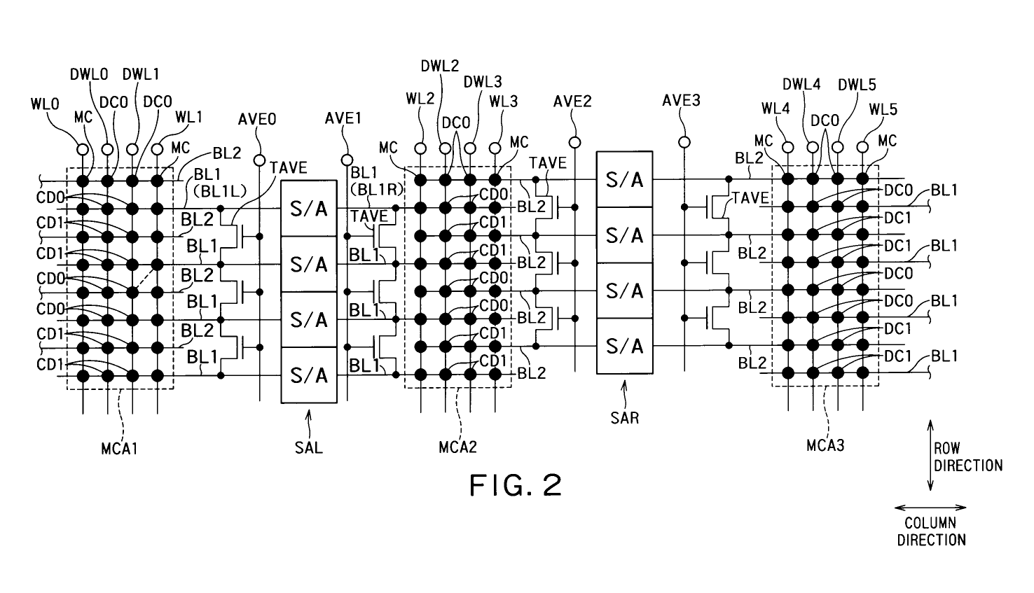

In FIG. 1, for convenience, a memory cell array MCA is displayed only on one side of the sense amplifier S/A. In practice, as shown in FIG. 2, the memory cell arrays MCA are disposed on both sides of the sense amplifier S/A. The sense amplifier S/A is connected to two bit lines BL provided for the memory cell arrays MCA on both sides of the sense amplifier S/A.

FIG. 2 is a diagram showing the arrangement relation between the memory cell array MCA and the sense amplifier S/A in the first embodiment. The memory cells MC are arranged in a matrix and form memory cell arrays MCA1 to MCA 3 (hereinbelow, also called MCA). The word line WL extends in the row direction and is disposed in the column direction as a first direction. The word line WL is connected to the gate of the memory cell MC. Although two word lines WL are shown on each of the right and left sides of the sense amplifier S/A in FIG. 2, usually, larger number of word lines WL are provided. For example, 256 word lines WL are provided on each of the right and left sides of the sense amplifier S/A.

A plurality of first bit lines BL1 and a plurality of second bit lines BL2 (hereinbelow, also called bit lines BL) extend in the column direction and are alternately arranged in the row direction as a second direction. The bit line BL is connected to the source or drain of the memory cell MC. Although eight bit lines BL are shown on each of the right and left sides of the sense amplifier S/A in FIG. 2, usually, larger number of bit lines BL are provided. For example, 1,024 bit lines BL are provided on each of the right and left sides of the sense amplifier S/A. The word lines WL and the bit lines BL are orthogonal to each other, and memory cells MC are provided at cross points of the word lines WL and the bit lines BL. The cell is called a cross-point cell. The row direction and the column direction may be interchanged.

Two dummy cells DC0 and two dummy cells DC1 are alternately arranged in the extending direction of the dummy word lines DWL (the row direction). Specifically, the dummy cells DC0 and DC1 are arranged in the row direction like DC0, DC0, DC1, DC1, DC0, DC0, DC1, DC1, . . . . To generate a reference current Iref, equal numbers of the dummy cells DC0 and the dummy cells DC1 are provided. The dummy word lines DWL extend in the row direction and are connected to the gates of the dummy cells DC0 and DC1. One dummy word line DWL is provided on each of the right and left sides of the sense amplifier S/A.

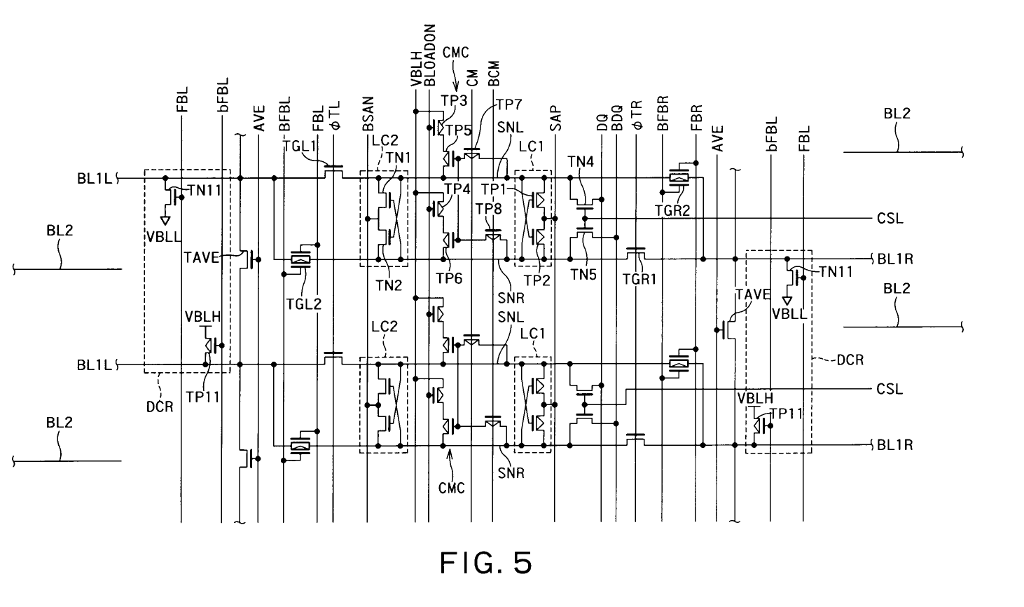

Prior to the data reading/writing operation, the dummy cells DC0 and the DC1 store data “0” and “1” of opposite polarities, respectively. An operation of writing data to the dummy cells DC0 and DC1 is usually performed immediately after power-on. After that, each time the dummy cell is activated by reading operation, writing operation, refreshing operation, or the like, the data “0” and “1” is written and continuously stored. The polarity denotes the logical value “0” or “1” of data. The dummy cells DC0 and DC1 are used for generating the reference current Iref at the time of detecting data in the memory cell MC. The reference current Iref is an almost intermediate current between current flowing in the “0” cell and current flowing in the “1” cell. A current mirror circuit (refer to FIG. 5) in the sense amplifier S/A passes current to the memory cell MC via the bit line BL. Consequently, the current according to data in the memory cell MC flows in a sense node in the sense amplifier S/A. According to the current flowing in the sense node which is higher or lower than the reference current Iref, the sense amplifier S/A identifies the logical value of data which is “1” or “0”.

Any of averaging signal lines AVE0 to AVE3 (hereinbelow, also called AVE) activates an averaging transistor TAVE in order to generate the reference current Iref. When the averaging transistor TAVE is turned on, a neighboring bit line is short-circuited. The data in the dummy cells DC0 and DC1 is averaged, thereby generating the reference current Iref.

The sense amplifier S/A is disposed between neighboring two memory cell arrays MCA and connected to a first bit line BL1 of each of the memory cell arrays MCA. Alternatively, the sense amplifier S/A is connected to a second bit line BL2 in each of the memory cell arrays MCA. Using data of one of the first bit lines BL1 as a reference, the sense amplifier S/A detects data transmitted to the other first bit line BL1. At this time, the reference current Iref flows to the first bit line BL1 as one of them. Alternatively, using the data of one of the second bit lines BL2 as a reference, the sense amplifier S/A detects data transmitted to the other second bit line BL2. At this time, the reference current Iref flows in the second bit line BL2 as one of them.

The sense amplifiers S/A are disposed on both sides of the memory cell array MCA and connected alternately to the bit lines BL. For example, when attention is paid to a memory cell array MCA2 in FIG. 2, the first bit lines BL1 disposed alternately are connected to the sense amplifiers S/A disposed on the right side of the memory cell array MCA2. The second bit lines BL2 disposed alternately with the first bit lines BL1 are connected to the sense amplifiers S/A disposed on the left side of the memory cell array MCA2. In other words, the bit lines BL disposed in the row direction in a memory cell array MCA are alternately connected to the sense amplifiers S/A disposed on the right and left sides. Each of the memory cell arrays MCA1 and MCA3 has such a connection relation of the sense amplifiers S/A and the bit lines BL.

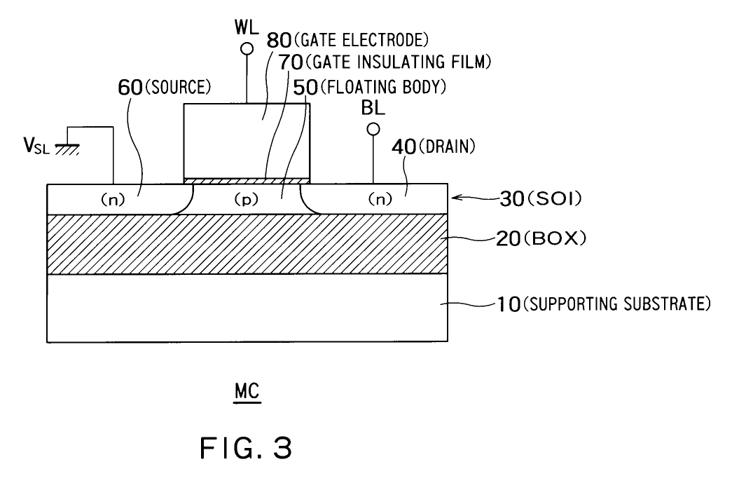

FIG. 3 is a cross section showing the structure of the memory cell MC. The dummy cell DC has a configuration similar to that of the memory cell MC. The memory cell MC is provided on an SOI substrate including a support substrate 10, a BOX layer 20, and an SOI layer 30. In the SOI layer 30, a source 60 and a drain 40 are provided. A floating body 50 is formed in the SOI layer 30 between the source 60 and the drain 40. The body 50 is a semiconductor of the conduction type opposite to that of the source 60 and the drain 40. In the embodiment, the memory cell MC is an N-type FET. The body 50 is electrically floated by partially or wholly surrounded by the source 60, the drain 40, the BOX layer 20, a gate insulating film 70, and an STI (Shallow Trench Isolation) (not shown). An FBC memory can store logical data (binary data) by the number of majority carriers in the body 50.

An example of a method of writing data to the memory cell MC will be described below. To write the data “1” to the memory cell MC, the memory cell MC is operated in a saturation state. For example, the word line WL is biased to 1.5V, and the bit line BL is biased to 1.5V. The source serves as a ground GND (0V). Consequently, impact ionization occurs around the drain, and a large amount of electron-hole pairs are generated. Electrons generated by the impact ionization flow in the drain, and the holes are stored in the body of low potential. When a current that flows when the holes are generated by the impact ionization and a forward current in the pn junction between the body and source are balanced, the body voltage enters a balanced state. The body voltage is about 0.7V.

At the time of writing the data “0”, the potential of the bit line BL is decreased to a negative voltage. For example, the potential of the bit line BL is decreased to −1.5V. By the operation, the pn junction between the body 50 and the drain 40 is largely biased in the forward direction. The holes stored in the body 50 are ejected to the drain 40, and the data “0” is stored in the memory cell MC.

An example of a method of reading data from the memory cell MC will be described below. In the data reading operation, the word line WL is activated as in the data writing operation but the potential of the bit line BL is set to a value lower than that in the writing of the data “1”. For example, the word line WL is set to 1.5V, and the bit line BL is set to 0.2V. The memory cell MC is operated in a linear region. The memory cell MC for storing the data “0” and the memory cell MC for storing the data “1” are different from each other with respect to threshold voltages of the memory cells MC depending on the difference in the number of holes stored in the body 50. By detecting the difference of threshold voltages, the data “1” and the data “0” is identified. The reason for setting the voltage of the bit line BL to be low at the time of reading is that, if the voltage of the bit line BL is set to be high and the memory cell MC is biased to a saturation state, there is the possibility that, in the case of reading the data “0”, the data “0” is changed to the data “1” due to the impact ionization.

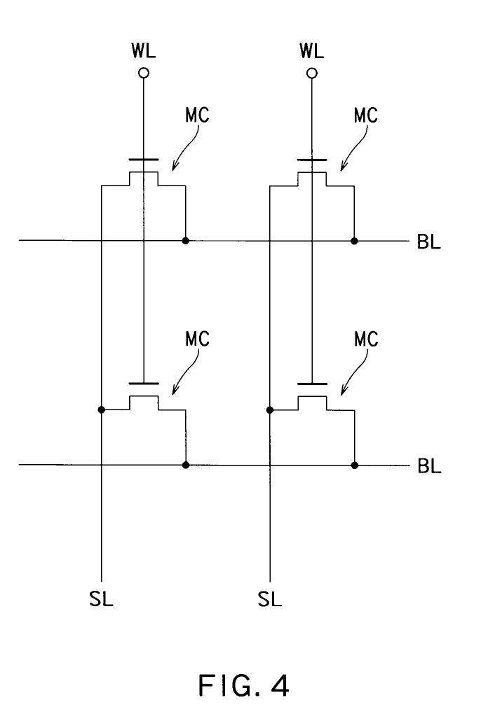

FIG. 4 is a circuit diagram showing the connection relation of the memory cell MC, the bit line BL, the word line WL, and the source line SL. The gate of the memory cell MC is connected to the word line WL. One of the drain and the source of the memory cell MC is connected to the bit line BL, and the other is connected to the source line SL.

FIG. 5 is a circuit diagram showing an example of the configuration of the sense amplifier S/A. In FIG. 5, two sense amplifiers S/A are shown. Since they have the same configuration, the configuration of only one of the sense amplifiers will be described.

In the embodiment, an open bit line configuration is employed. The sense amplifier S/A is connected to the first bit line BL1 provided on each of the right and left sides. The sense amplifier S/A includes a pair of sense nodes SNL and SNR. The sense node SNL is connected to a first bit line BL1L on the left side via a transfer gate TGL1, and is connected to a first bit line BL1R on the right side via a transfer gate TGR2. The sense node SNR is connected to the first bit line BL1L via the transfer gate TGL2, and is connected to the first bit line BL1R via the transfer gate TGR1.

The transfer gates TGL1 and TGR1 are on/off controlled by signals ΦTL and ΦTR. The transfer gate TGL2 is on/off controlled by signals FBL and bFBL. The transfer gate TGR2 is on/off controlled by signals FBR and bFBR. A signal b** is used as the name of a signal for activating the transfer gate or the like at a low potential.

For example, in the data reading operation, the sense amplifier S/A reads data in the memory cell MC, outputs the data to the outside via the DQ buffer DQB, and rewrites the data into the memory cell MC. In the case of reading data from the “1” cell connected to the bit line BLL, the transfer gates TGL1 and TGR1 are turned on, and the transfer gates TGL2 and TGR2 are turned off. Since the threshold voltage of the “1” cell is relatively low, the current flowing from the sense node SNL to the “1” cell becomes larger than Iref. Since the current flowing from the sense node SNR to the bit line BLR is Iref, the potential of the sense node SNL is lower than that of the sense node SNR. The sense amplifier S/A amplifies the potential difference between the sense nodes SNL and SNR and latches the amplified difference. On the other hand, to rewrite the data “1” to the memory cell MC, a high potential has to be given to the bit line BLL. By turning off the transfer gate TGL1 and turning on the transfer gate TGL2, the sense node SNR of high potential is connected to the bit line BLL.

The sense amplifier S/A includes cross-couple dynamic latch circuits (hereinbelow, called latch circuits) LC1 and LC2. The latch circuit LC1 is made of two p-type transistors TP1 and TP2 connected in series between the sense nodes SNL and SNR. The gate of the transistor TP1 is connected to the sense node SNR, and the gate of the transistor TP2 is connected to the sense node SNL. That is, the gates of the transistors TP1 and TR2 are cross-coupled to the sense nodes SNL and SNR. The latch circuit LC2 is made of two n-type transistors TN1 and TN2 connected in series between the sense nodes SNL and SNR. The gate of the transistor TN1 is connected to the sense node SNR, and the gate of the transistor TN2 is connected to the sense node SNL. That is, the gates of the transistors TN1 and TN2 are also cross-coupled to the sense nodes SNL and SNR. The latch circuits LC1 and LC2 are driven by activating signals SAP and bSAN, respectively.

A dummy cell restoring unit DCR includes an n-type transistor TN11 and a p-type transistor TP11. The transistor TN11 is connected between a potential VBLL and the first bit line BL1L (BL1R). The gate of the transistor TN11 is connected to a feedback signal FBR (FBL). VBLL denotes a low potential applied to the bit line BL at the time of writing the data “0”. The transistor TP11 is connected between a potential VBLH and the first bit line BL1L (BL1R). The gate of the transistor TP11 is connected to the feedback signal bFBR (bFBL). The transistors TN11 and TP11 are connected to two neighboring first bit lines BL1 and are alternately connected to the first bit line BL1. The dummy cell restoring unit DCR is used to restore a dummy cell DC.

The sense amplifier S/A further includes a current mirror type current load circuit (hereinbelow, called a mirror circuit) CMC made of P-type transistors TP3 to TP8. The mirror circuit is constructed so as to pass equal currents to the sense nodes SNL and SNR. The transistors TP3 and TP4 are controlled by a load signal bLOADON and functions as a switching element for switching between a power source VBLH and the mirror circuit. VBLH denotes a high potential to be given to the bit line BL at the time of writing the data “1” to the memory cell MC. The current load circuit is not limited to such a mirror circuit. For example, the latch circuit LC1 may be provided with the function of the current load circuit. In this case, the mirror circuit CMC is unnecessary.

An N-type transistor TN4 is connected between a DQ line and the sense node SNL, and an N-type transistor TN5 is connected between a bDQ line and the sense node SNR. The gates of the transistors TN4 and TN5 are connected to a column selection line CSL. The DQ line and the bDQ line are connected to a DQ buffer. From the DQ buffer, the lines are connected to I/O pads directly or via buffers in a few stages. At the time of reading data, to output data from the memory cell MC to the outside, the data is temporarily stored. At the time of writing data, to transmit data from the outside to the sense amplifier S/A, the data is temporarily stored. Therefore, the column selection line CSL is activated at the time of reading data to the outside or writing data from the outside, thereby enabling the sense nodes SNL and SNR to be connected to the DQ buffer. In a refresh operation, the column selection line CSL maintains an inactive state.

The refresh operation is an operation of temporarily reading data from a memory cell MC, latching the data in the sense amplifier S/A, and rewriting data of the same logic as the latched data to the memory cell MC. The refresh operation is executed to prevent the “1” cell which is not selected and connected to the activated word line WL from changing to the “0” cell due to the charge pumping phenomenon. The charge pumping phenomenon is a phenomenon that electrons trapped in a surface state existing in the interface between the silicon substrate and the gate insulating film and holes in the body are recombined and, as a result, the holes disappear from the body.

“Activation” denotes turn-on or driving of an element or a circuit, and “inactivation” denotes turn-off or stop of an element or a circuit. It should be therefore noted that an activation signal is a high-level (high potential level) signal or a low-level (low potential level) signal. For example, an NMOS transistor is activated by setting the gate to the high level. On the other hand, a PMOS transistor is activated by setting the gate to the low level.

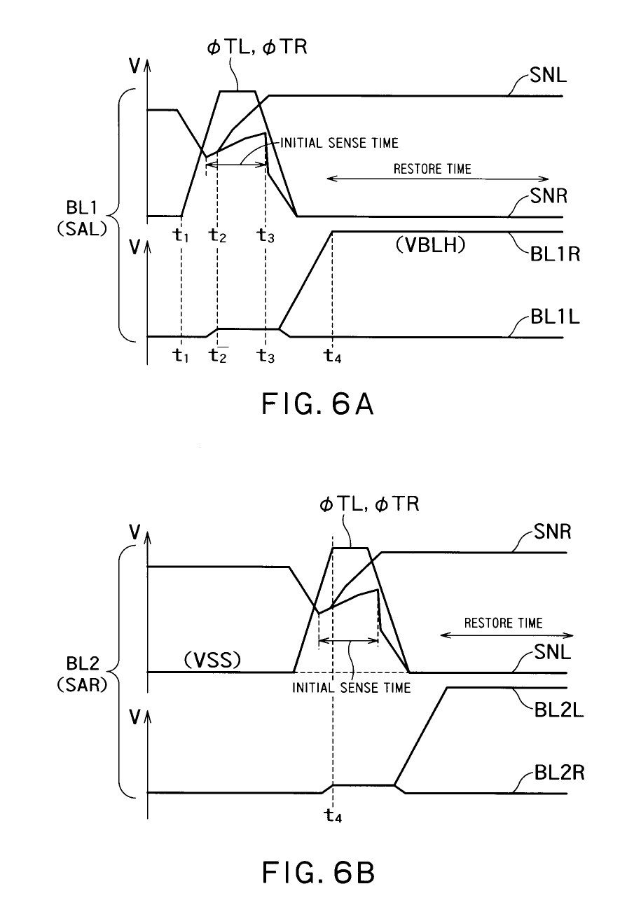

FIGS. 6A and 6B are timing charts showing data reading operation of an FBC memory device according to the embodiment. In the embodiment, data is read from a sense amplifier line SAL as show in FIG. 6A and, after that, data is read from a sense amplifier line SAR as shown in FIG. 6B. In the following reading operation, information data in a memory cell MC in the memory cell array MCA2 shown in FIG. 2 is read.

First, the sense amplifier line SAL shown in FIG. 2 is activated (t1). More specifically, the signals ΦTL and ΦTR shown in FIG. 5 are activated to the high level to turn on the transfer gates TGL1 and TGR2. Further, the current mirror circuit CMC is activated. Simultaneously, by activating the averaging signal line AVE0 and the dummy word line DWL1 in FIG. 2, the reference current Iref flows in the first bit line BL1L on the left side of the sense amplifier line SAL. On the other hand, by activating the word line WL2 in FIG. 2, information data is transmitted to the first bit line BL1R on the right side of the sense amplifier line SAL. At this time, as shown at t2 in FIG. 6A, a signal difference occurs between the sense nodes SNL and SNR according to the polarity of information data. In the embodiment, a memory cell connected to the first bit line BL1R is a “1” cell.

When the signal difference between the sense nodes SNL and SNR is sufficiently developed at t3, the sense amplifier S/A drives LC1 and LC2 shown in FIG. 5. By the driving, the sense amplifier S/A amplifies the signal difference between the sense nodes SNL and SNR and latches the amplified signal difference. As described above, at times t1 to t3, each of the sense amplifiers S/A in the sense amplifier line SAL detects information data via the first bit line BL1R in the memory cell array MCA2 in FIG. 2.

It should be noted that, in the data reading period (initial sense period) from t1 to t3, the sense amplifier line SAR shown in FIG. 6B fixes the voltage of the second bit line BL2 to the potential VBLL. The potential VBLL is a bit line potential at the time of writing the data “0” and is equal to the source line potential VSL (for example, ground potential). In the memory cell array MCA2 shown in FIG. 2, during the reading period in which information data is transmitted through the first bit line BL1R, the voltage of the second bit line BL2 adjacent to the first bit line BL1 in the row direction is fixed. That is, the bit lines BL are driven alternately (intermittently) and the voltage of the other bit lines BL which are not driven is fixed. In other words, the voltage of the bit lines BL is fixed alternately (intermittently), and the other bit lines are driven. Therefore, at the time of reading data, the information data transmitted through the first bit line BL1 is not influenced by capacitive coupling between the first bit line BL1 and the second bit line BL2. That is, at the time of reading data, the information data transmitted through the first bit line BL1 is not influenced by noise from the second bit line BL2. Since the second bit line BL2 plays the role of a shield, the information data transmitted through the first bit line BL1 is not easily influenced by the other first bit lines BL1. As a result, the FBC memory in the embodiment can accurately detect the information data to be read without being influenced by a neighboring bit line.

At t4 and after that, the sense amplifier line SAL executes restore operation (refresh operation) for rewriting the read data to the memory cell MC. At this time, the feedback lines FBR and bFBR shown in FIG. 5 are activated and the transfer gate TGR2 is turned on. The sense node SNL latching the high potential level is connected to the first bit line BL1R. As a result, the data “1” is rewritten to the memory cell MC connected to the first bit line BL1R.

A memory cell MC disposed at the intersection between the activated word line WL2 and the second bit line BL2 is a not-selected memory cell but is influenced by the charge pumping phenomenon. Therefore, as shown in FIG. 6B, the sense amplifier line SAR executes the refresh operation on the memory cell MC disposed at the interaction between the word line WL2 and the second bit line BL2. In the refresh operation, in a manner similar to the sense amplifier line SAL shown in FIG. 6A, the sense amplifier line SAR temporarily reads data, and rewrites the data to the memory cell MC. At this time, the first bit line BL1R is in the period of the restore operation, and the first bit line BL1R is fixed to the bit line potential in the restore operation. In the embodiment, at this time, the first bit line BL1R is fixed to a high-level potential (VBLH) for writing “1”. That is, also in the case of driving the second bit line BL2, the bit lines BL are driven alternately (intermittently), and the voltage of the other bit lines BL1 which are not driven is fixed. In other words, the voltage of the bit lines BL is fixed alternately (intermittently), and the other bit lines are driven. Therefore, in the refresh operation of the memory cell MC connected to the second bit line BL2, the information data transmitted through the second bit line BL2 is not influenced by noise from the first bit line BL1R. Since the first bit line BL1R plays the role of a shield, the information data transmitted through the second bit line BL2 is not easily influenced by the other bit lines BL2. As a result, the FBC memory in the embodiment does not erroneously detect data during the refresh operation.

When the potential of the first bit line BL1 or the potential of the second bit line BL2 is fixed, the value of the fixed potential may be arbitrary. Therefore, the value of the fixed potential may be a potential other than VBLL, VBLH, and VSL.

As understood with reference to FIGS. 6A and 6B, the initial sense period of the first bit line BL1 and the initial sense period of the second bit line BL2 are temporally deviated from each other. Consequently, the cycle time as a whole increases only by an almost the initial sense period. However, the second bit line BL2 is refreshed during the restoring period of the first bit line BL1 and, usually, a period of detecting data (initial sense period) is much shorter than a period of rewriting data (restore period). Therefore, the increase in the cycle time is almost ignorable.

In a conventional 1T-1C type DRAM and a conventional ferroelectric memory, in the initial sense, the potential is floated in a state where all of the bit lines are connected to memory cells. If the potentials of the bit lines are alternately fixed at random like a potential of a bit line is fixed to writing potential of “1” and another bit line is fixed to writing potential of “0”, data of a memory cell connected to the bit line is destroyed. On the other hand, if the potential of the bit line is left in the floating state, due to the influence of capacitive coupling with the neighboring bit line, accurate data detection cannot be executed. Therefore, the means of the embodiment cannot be applied to a conventional 1T-1C type DRAM and a conventional ferroelectric memory.

As shown in FIGS. 6A and 6B, to make the initial sense period of the first bit line BL1 and the initial sense period of the second bit line BL2 temporally deviated from each other, an address for selecting either the first bit line BL1 or the second bit line BL2 is necessary. In the following, the address for selecting either the first bit line BL1 or the second bit line BL2 will be called an “LR identification address”.

Conventionally, one row address is assigned to one word line WL. In the embodiment, however, even in the case where the same word line WL is selected, it is necessary to make the initial sense period of the first bit line BL1 and the initial sense period of the second bit line BL2 temporally deviated from each other. Therefore, by the LR identification address, the first bit line BL1 and the second bit line BL2 are identified.

The LR identification address is added to a row address for selecting a word line WL. For example, one bit is added to the least significant digit of the row address, and the added bit is set as the LR identification address. For example, in the case where the LR identification address is “0”, the sense amplifier line SAL, that is, the first bit line BL1 is selected. In the case where the LR identification address is “1”, the sense amplifier line SAR, that is, the second bit line BL2 is selected.

Since a row address is activated quicker than a column address, a sense amplifier line including an object to be read can be activated more quickly. Therefore, in the embodiment, access time is not delayed.

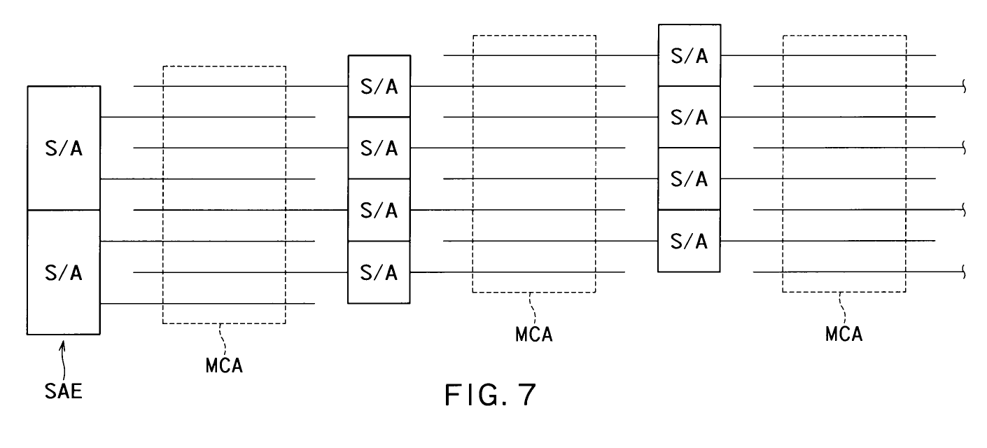

FIG. 7 is a schematic diagram showing an end sense amplifier line SAE. The end sense amplifier SAE at the end of arrangement of a plurality of memory cell arrays MCA is a 2-cell/bit type (twin cell type) sense amplifier. The end sense amplifier SAE is connected to neighboring two first bit lines BL1 or neighboring two second bit lines BL2. The 2-cell/bit type is a type of storing data of the opposite logics in a pair of memory cells MC to store 1-bit data. The sense amplifier SAE is constructed to use one of data of the pair of memory cells MC and detect the other data. By setting a 2-cell/bit type sense amplifier as the end sense amplifier SAE, waste in the memory cell array can be suppressed.

### Second Embodiment

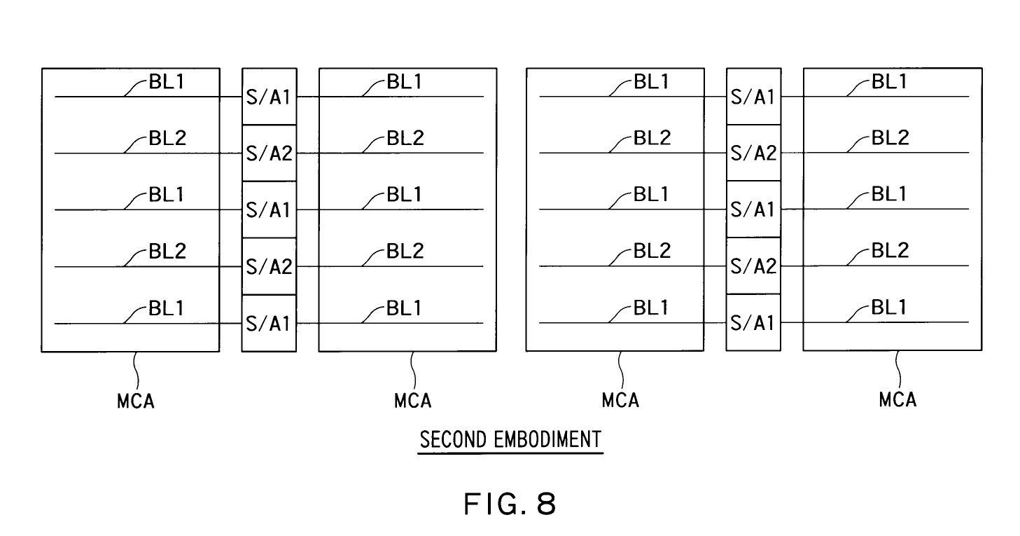

FIG. 8 shows the configuration of an FBC memory as a second embodiment of the present invention. In the second embodiment, sense amplifiers S/A1 and S/A2 are disposed only one side of the memory cell array MCA and are not disposed on the other side. Therefore, the sense amplifiers S/A1 connected to the first bit lines BL1 and the sense amplifiers S/A2 connected to the second bit line BL2 are alternately arranged in the row direction.

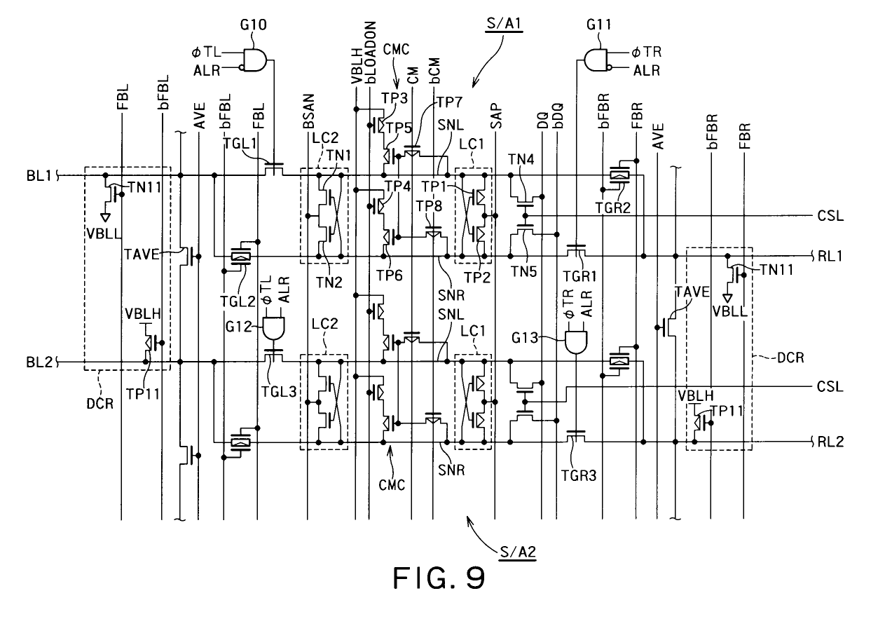

FIG. 9 is a circuit diagram showing the configuration of the sense amplifiers S/A1 and S/A2 in the second embodiment. The sense amplifier S/A1 is a sense amplifier connected to the first bit line BL1, and the sense amplifier S/A2 is a sense amplifier connected to the second bit line BL2.

The sense amplifier S/A1 is different from the sense amplifier of the first embodiment with respect to the point that the sense amplifier S/A1 has AND gates G10 and G11. The other configuration of the sense amplifier S/A1 is similar to that of the sense amplifier of the first embodiment. The AND gate G10 receives the signal ΦTL and an inversion signal of an address ALR, and outputs AND computation results to the gate of the transfer gate TGL1. The AND gate G11 receives the signal ΦTR and an inversion signal of an address ALR, and outputs AND computation results to the gate of the transfer gate TGR1. The address ALR is an LR identification address included in a row address.

The sense amplifier S/A2 is different from the sense amplifier of the first embodiment with respect to the point that the sense amplifier S/A2 has AND gates G12 and G13. The other configuration of the sense amplifier S/A2 is similar to that of the sense amplifier of the first embodiment. The AND gate G12 receives the signal ΦTL and the address ALR, and outputs AND computation results to the gate of the transfer gate TGL3. The AND gate G13 receives the signal ΦTR and the address ALR, and outputs AND computation results to the gate of the transfer gate TGR3. The transfer gate TGL3 is connected between the sense node SNL of the sense amplifier S/A2 and the second bit line BL2 on the left side of the sense amplifier S/A2. The transfer gate TGR3 is connected between the sense node SNR of the sense amplifier S/A2 and the second bit line BL2 on the right side of the sense amplifier S/A2.

By the gates G10 to G13, when the LR identification address is “0”, the sense amplifier S/A1 is selected. When the LR identification address is “1”, the sense amplifier S/A2 is selected. In such a manner, the timings of the initial sense operation of the sense amplifier S/A1 and the initial sense operation of the sense amplifier S/A2 can be deviated from each other. The operation of the FBC memory in the second embodiment is similar to that of the FBC memory in the first embodiment. Therefore, the second embodiment can obtain effects similar to those of the first embodiment.

In the foregoing embodiments, the memory cell MC may be a p-type FET. In this case, the memory cell MC stores electrons or releases electrons, thereby storing data. In this case, the polarity of the potential of the word line WL and that of the bit line BL are opposite to each other.

Although the source potential is the ground potential in the embodiment, it may be set to a potential other than the ground potential.

The sense amplifier of the embodiment supplies current from the current mirror CMC to the memory cell MC at the time of reading data by employing a PMOS load. Alternatively, the FBC memory in the embodiment may employ an NMOS load and pass current from the memory cell MC to the current mirror CMC at the time of reading data. In this case, at the time of restoring data, it is sufficient to connect the pair of sense nodes SNL and SNR to the bit lines to which they were connected at the time of reading data. In the case of employing an NMOS load, the logics of data latched by the pair of sense nodes SNL and SNR are not inverted.

What is claimed is:

1. A semiconductor storage device comprising:
a plurality of memory cells having sources, drains, and gates, including floating bodies in electric floating states, the memory cells storing data according to the number of carriers in the floating bodies;
a plurality of word lines connected to gates of the memory cells and arranged in a first direction;
a plurality of first bit lines and a plurality of second bit lines connected to sources or drains of the memory cells and arranged alternately in a second direction intersecting with the first direction; and
first and second sense amplifiers provided in correspondence with the first and the second bit lines and sensing data of the memory cells,
wherein in a data reading operation, the first sense amplifier activates the first bit lines to sense data via the first bit lines in a state where voltage of the second bit lines is fixed, and
after sensing of the data of the first bit line, the second sense amplifier activates the second bit lines to sense data via the second bit lines in a state where voltage of the first bit lines is fixed.

2. The semiconductor storage device according to claim 1, wherein in a data reading operation, the first sense amplifier activates the first bit lines to sense data via the first bit lines in a state where voltage of the second bit lines is fixed to the voltage of the second bit line at the time of writing data, and
after sensing of the data of the first bit line, the second sense amplifier activates the second bit lines to sense data via the second bit lines in a state where voltage of the first bit lines is fixed to a voltage of the first bit line at the time of restoring the data.

3. The semiconductor storage device according to claim 1, wherein the first and the second sense amplifiers are disposed between a plurality of memory cell arrays in which the plurality of memory cells are two-dimensionally disposed, the first and the second sense amplifiers using data of a memory cell in one of the memory cell arrays as a reference to sense data of a memory cell in the other memory cell array,
the first sense amplifier connected to the first bit line is disposed on one side of the memory cell array, and the second sense amplifier connected to the second bit line is disposed on the other side of the memory cell array.

4. The semiconductor storage device according to claim 2, wherein the first and the second sense amplifiers are disposed between a plurality of memory cell arrays in which the plurality of memory cells are two-dimensionally disposed, the first and the second sense amplifiers using data of a memory cell in one of the memory cell arrays as a reference to sense data of a memory cell in the other memory cell array,
the first sense amplifier connected to the first bit line is disposed on one side of the memory cell array, and the second sense amplifier connected to the second bit line is disposed on the other side of the memory cell array.

5. The semiconductor storage device according to claim 1, wherein a row address for selecting the word line includes an address for selecting either the first bit line or the second bit line.

6. The semiconductor storage device according to claim 2, wherein a row address for selecting the word line includes an address for selecting either the first bit line or the second bit line.

7. The semiconductor storage device according to claim 3, wherein a row address for selecting the word line includes an address for selecting either the first bit line or the second bit line.

8. The semiconductor storage device according to claim 1, further comprising an end sense amplifier provided for a memory cell array at the end of arrangement of a plurality of memory cell arrays in which a plurality of memory cells are two-dimensionally disposed, the memory cell arrays being connected to two first bit lines adjacent to each other or the two second bit lines adjacent to each other.

9. The semiconductor storage device according to claim 2, further comprising an end sense amplifier provided for a memory cell array at the end of arrangement of a plurality of memory cell arrays in which a plurality of memory cells are two-dimensionally disposed, the memory cell arrays being connected to two first bit lines adjacent to each other or the two second bit lines adjacent to each other.

10. The semiconductor storage device according to claim 3, further comprising an end sense amplifier provided for a memory cell array at the end of arrangement of a plurality of memory cell arrays in which a plurality of memory cells are two-dimensionally disposed, the memory cell arrays being connected to two first bit lines adjacent to each other or the two second bit lines adjacent to each other.

11. The semiconductor storage device according to claim 5, further comprising an end sense amplifier provided for a memory cell array at the end of arrangement of a plurality of memory cell arrays in which a plurality of memory cells are two-dimensionally disposed, the memory cell arrays being connected to two first bit lines adjacent to each other or the two second bit lines adjacent to each other.

12. The semiconductor storage device according to claim 1, wherein a timing of the data reading operation of the first sense amplifier and a timing of the data reading operation of the second sense amplifier are deviated from each other only by a data sensing period of the first or the second sense amplifier.

13. The semiconductor storage device according to claim 2, wherein a timing of the data reading operation of the first sense amplifier and a timing of the data reading operation of the second sense amplifier are deviated from each other only by a data sensing period of the first or the second sense amplifier.

14. The semiconductor storage device according to claim 3, wherein a timing of the data reading operation of the first sense amplifier and a timing of the data reading operation of the second sense amplifier are deviated from each other only by a data sensing period of the first or the second sense amplifier.

15. The semiconductor storage device according to claim 5, wherein a timing of the data reading operation of the first sense amplifier and a timing of the data reading operation of the second sense amplifier are deviated from each other only by a data sensing period of the first or the second sense amplifier.

16. The semiconductor storage device according to claim 1, wherein the first and the second sense amplifiers are disposed between two memory cell arrays including the plurality of memory cells, and
the first and the second sense amplifiers are arranged alternately in the first direction.

17. The semiconductor storage device according to claim 16, wherein in a data reading operation, the first sense amplifier activates the first bit lines to sense data via the first bit lines in a state where voltage of the second bit lines is fixed to the voltage of the second bit line at the time of writing data, and
after sensing of the data of the first bit line, the second sense amplifier activates the second bit lines to sense data via the second bit lines in a state where voltage of the first bit lines is fixed to a voltage of the first bit line at the time of restoring the data.

18. The semiconductor storage device according to claim 16, further comprising:
a first transfer gate connected between the first bit line and the first sense amplifier;
a second transfer gate connected between the second bit line and the second sense amplifier; and
a logic gate connected to the first transfer gate, the logic gate calculating logical sum of a control signal activated when the first and the second sense amplifiers detect data and an address for selecting either the first bit line or the second bit line, and the logic gate controlling the first and the second transfer gates on the basis of the control signal and the address.
